(19) United States
(12) Patent Application Publication
(10) Pub. No.: US 2026/0328549 A1
(43) Pub. Date: Oct. 22, 2026

(54) ELECTRONIC DEVICE WITH DUAL-PATH FLEXIBLE ELECTRICAL CONNECTOR

(71) Applicant: L3Harris Technologies, Inc., Melbourne, FL (US)

(72) Inventors: Eric SOBKOWIAK, Liberty Township, OH (US); Tyler FAUCETT, Cincinnati, OH (US)

(21) Appl. No.: 19/184,554

(22) Filed: Apr. 21, 2025

(51) Int. Cl. F42C 15/40; F42B 3/103; F42B 3/198; H01R 12/70; H01R 12/71

(52) U.S. Cl. CPC F42C 15/40; F42B 3/103; F42B 3/198; H01R 12/7047; H01R 12/7076; H01R 12/718

(57) ABSTRACT

An electronic device comprises: a housing enclosing a cavity; a lid rotatable along a hinge axis onto an open end of the housing to bound the cavity; two load devices connected to the lid; a circuit board disposed in the cavity, spaced apart from the open end of the housing; and a flexible electrical connector including: a common end terminal connected to the circuit board, and two ribbon-shaped branches extending from the common end terminal to the two load devices, respectively, to deliver substantially the same amount of energy from the circuit board to the two load devices in response to the common end terminal receiving a voltage signal from the circuit board. The two branches of the flexible electrical connector are oriented to bend along axes that are parallel to the hinge axis in the closed position of the lid.

### TECHNICAL FIELD

The present disclosure relates to an electronic device including a dual-path flexible electrical connector having parallel signal paths with the same electrical characteristics to deliver substantially the same energy to dual load devices.

### BACKGROUND

Electronic Safe and Arm Devices (ESADs) are high-voltage electronic initiation devices employed in a variety of contexts to ensure that a system remains safe until its intended deployment. In fuzing and arming systems, for example, safety is generally ensured by requiring a certain sequence of events to occur before enabling deployment. Upon identifying that required use conditions have been met, an ESAD provides safe initiation of operational events such as arming, firing, and launching, e.g., on launch vehicle platforms. Specifically, an ESAD delivers a high-voltage signal to activate an energetic in an initiator device, such as a Low Energy Exploding Foil Initiator (LEEFI), which then propagates to a main device such as a warhead. This arrangement provides failsafe operation and isolation, which avoids accidental or premature arming of the system.

Having redundant initiators in an arming system would improve overall reliability. However, implementing more than one initiator in existing single-initiator ESAD architectures presents manufacturing, testing, and operational challenges. Such redundancy would require a design that is robust and practical for assembly and testing and capable of dependably delivering the same amount of energy to each initiator in parallel.

### BRIEF DESCRIPTION OF THE DRAWINGS

FIG. 1 is a perspective view illustrating a dual-initiator electronic safe and arm device (ESAD) with its lid in an open position.

FIG. 2 is a perspective view illustrating the ESAD of FIG. 1 with the lid in a closed position.

FIG. 3 is a top plan view of the ESAD of FIG. 1 with the lid cut away to show the orientation of the flexible electrical connector relative to the high-voltage circuit board and the initiators in a closed-lid configuration.

FIG. 4 is a side view in elevation of the ESAD of FIG. 1 with a portion of the housing cut away to show the contents of the interior cavity.

FIG. 5 is a diagram illustrating the flexible electrical connector in FIGS. 3 and 4 in a flat, uninstalled configuration.

FIG. 6 is a cross-sectional side view of the flexible electrical connector along line VI-VI in FIG. 5.

FIG. 7 is a plan view of a primary side of the flexible dielectric support layer of the flexible electrical connector of FIG. 5 showing outbound metal layers along the first and second ribbon-shaped branches.

FIG. 8 is a plan view of a secondary side of the flexible dielectric support layer of the flexible electrical connector of FIG. 5 showing return metal layers along the first and second ribbon-shaped branches.

FIG. 9 is a plan view showing a cover layer of the flexible electrical connector of FIG. 5.

FIG. 10 is a diagram illustrating the flexible electrical connector of FIG. 5 in an installed configuration in which the flexible electrical connector bends along parallel axes.

FIG. 11 is a functional flow diagram summarizing operations performed to manufacture a dual-initiator ESAD.

### DESCRIPTION

### Overview

According to a disclosed embodiment, an electronic device, such as an ESAD, comprises a housing enclosing a cavity and having an open end, a lid rotatable along a hinge axis onto the open end of the housing, the lid having an interior side that, in a closed position of the lid, bounds the cavity at the open end of the housing, and first and second load devices, such as initiator devices, coupled to the lid. The electronic device further includes a circuit board disposed in the cavity, spaced apart from the open end of the housing, and a flexible electrical connector that includes: a common end terminal connected to the circuit board, and first and second ribbon-shaped branches extending from the common end terminal to the first and second load devices, respectively, to deliver substantially the same amount of energy from the circuit board to the first and second load devices in response to the common end terminal receiving a voltage signal from the circuit board. The first and second branches of the flexible electrical connector are oriented to bend along axes that are parallel to the hinge axis in the closed position of the lid.

### Example Embodiments

Among the challenges of introducing dual-redundant initiators in an ESAD is providing circuitry and electrical connections that have the same electrical characteristics for both initiators, thereby ensuring that the firing characteristics are the same for both initiators. Another challenge is to avoid making reliability and safety testing more complicated despite introduction of a second initiator by performing only a single series of reliability and safety testing to characterize the firing characteristics of both initiators. To enable testing of the electronics without explosives present, a robust architecture for assembly should enable the initiators to be mounted as late as possible in the assembly process and at a distance from the high-voltage circuit board of the ESAD that supplies energy to the initiators. These challenges are addressed by the described example implementations of a dual-initiator ESAD, including a flexible electrical connector capable of delivering energy to dual initiators, as well as the described method of manufacturing a dual-initiator ESAD. It will be appreciated, nevertheless, that the principles elucidated by the disclosed examples may have applicability in other dual-load electronic devices that would benefit from reliable delivery of the same power level or amount of energy to two loads in parallel from a common source that is spaced apart from the load devices.

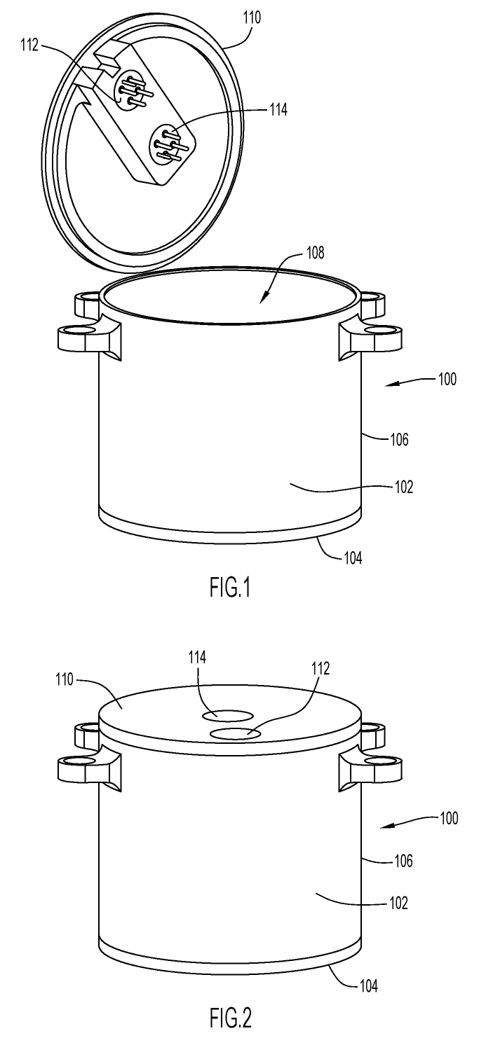

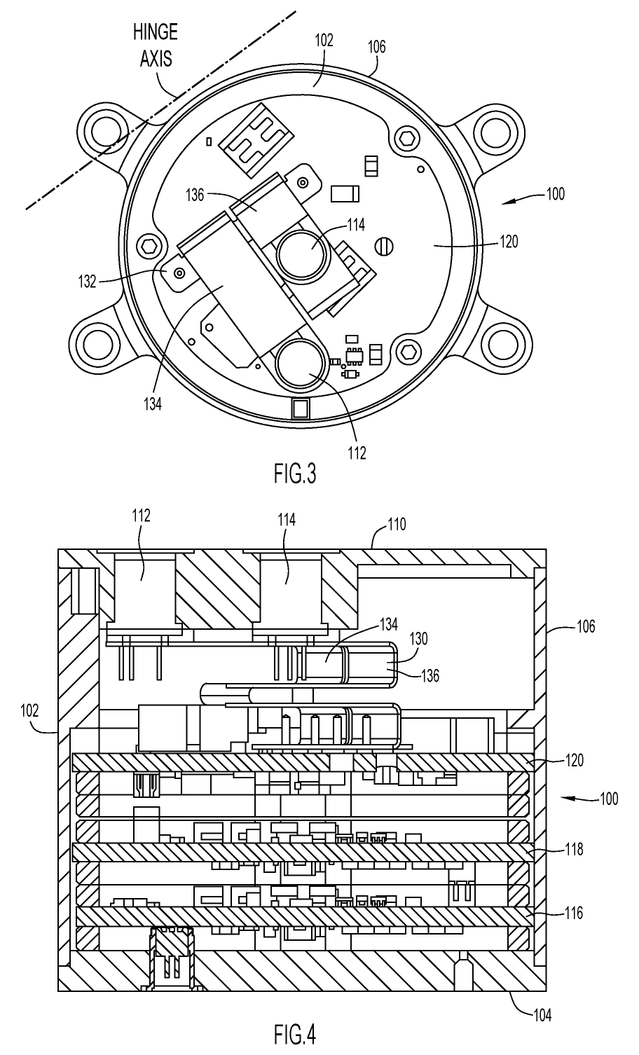

FIG. 1 is a perspective view illustrating a non-limiting example of an ESAD 100 having dual-redundant initiators with the lid of the ESAD in an open position. FIG. 2 is a perspective view of the ESAD of FIG. 1 with the lid in a closed position. The example ESAD shown in FIGS. 1 and 2 has a "common mini" form factor. The dual-redundant initiators for the common-mini-based ESAD can be exploding foil initiators (EFIs), such as Low Energy Exploding Foil Initiators (LEEFIs), for example. ESAD 100 includes a sleeve-like housing 102 having a generally cylindrical shape with a substantially circular plate at one end forming a closed bottom 104, an annular sidewall 106 having a substantially circular transverse cross section and extending from the bottom 104, and an open, top end opposite the closed, bottom end. Housing 102 defines and encloses a substantially cylindrical cavity 108 in the interior bounded by the sidewall 106 and bottom 104. A lid 110 having a generally circular, plate-like shape is rotatable along a hinge axis onto the open end of housing 102. The orientation of the hinge axis is represented by the dashed line in FIG. 3, which illustrates a top plan view of ESAD 100 with lid 110 cut away to show interior components. In the closed position of lid 110, shown in FIG. 2, the interior side of lid 110 bounds cavity 108 at the open end of housing 102. As seen in FIG. 1, first and second initiator devices 112 and 114 (e.g., LEEFIs) are mounted on lid 110 with connection pins of initiator devices 112, 114 extending downward from an interior side of lid 110. In FIG. 3, initiator devices 112, 114 are positioned according to the closed-lid configuration despite lid 110 itself being cut away to enable visualization of the interior of cavity 108.

FIG. 4 is a side view of ESAD 100 with lid 110 in the closed position and part of sidewall 106 cut away to expose the contents of cavity 108. Within cavity 108, ESAD 100 includes a set of circuit boards 116, 118, 120, such as rigid printed wiring boards (PWBs). Each of circuit boards 116, 118, 120 has a generally circular, disk-like shape (see, e.g., the top view of uppermost circuit board 120 in FIG. 3) and lies along a plane parallel to bottom 104 of housing 102. Circuit boards 116, 118, 120 are spaced apart from each other and are arranged in a stack having a lower end toward bottom 104 and an upper end toward the open end of housing 102 (shown as a vertical stack in the orientation shown in FIG. 4). As seen in FIG. 4, the uppermost circuit board 120 is spaced apart from the open end of housing 102 and, in the closed position of lid 110, uppermost circuit board 120 is therefore spaced apart from lid 110 and initiator devices 112, 114 mounted on the interior side of lid 110. While the non-limiting example shown in FIG. 4 includes three, disk-shaped circuit boards arranged in a stack, in general, the ESAD circuitry can be arranged in any suitable manner within the interior cavity, and the ESAD can have other shapes and form factors.

Uppermost circuit board 120 can be a high-voltage PWB that includes circuitry capable of generating a high-voltage signal to activate initiator devices 112 and 114. As used herein, the term "high-voltage signal" refers to a signal having a voltage of at least 100 volts and may be several hundred volts. Such a high-voltage signal is to be distinguished from, among other things, wire communication signals, which are typically no more than a few volts. By way of a non-limiting example, high-voltage circuit board 120 may include a high-voltage converter that generates a firing energy at a high voltage, e.g., 1,000 volts. The high-voltage firing energy can be stored on a firing capacitor, which can be discharged to deliver a specific amount of energy to activate initiator devices 112, 114.

High-voltage circuit board 120 is connected to initiator devices 112, 114 by a flexible electrical connector 130, shown in a flat, uninstalled configuration in FIG. 5. Flexible electrical connector 130 includes, at one end, a common end terminal 132 or "end strip" which can be connected to high-voltage terminals or pins on high-voltage circuit board 120. In this example, common end terminal 132 has a generally rectangular shape with a longer, longitudinal "length" dimension extending in a first direction and a shorter, transverse "width" dimension extending in a second direction, perpendicular to the length dimension. Flexible electrical connector 130 further includes first and second ribbon-shaped connector branches 134, 136 that extend longitudinally (along their longer "length" dimension), side-by-side from a longitudinal side of common end terminal 132 in the second direction, i.e., in a direction perpendicular to the first direction and to the length dimension of the common end terminal 132. First ribbon-shaped branch 134 terminates at its distal end in a first end terminal 138, and second ribbon-shaped branch 136 terminates at its distal end in a second end terminal 140. First and second end terminals 138, 140 are configured to be connected to first and second initiator devices 112, 114, respectively, as will be described in greater detail. By way of a non-limiting example, the overall length of flexible electrical connector 130 from the end terminals to the opposite end of the common end terminal can be approximately 3 to 4 inches, and the overall width of flexible electrical connector 130 (i.e., the "length" of common end terminal) can be approximately 1.0 to 1.5 inches.

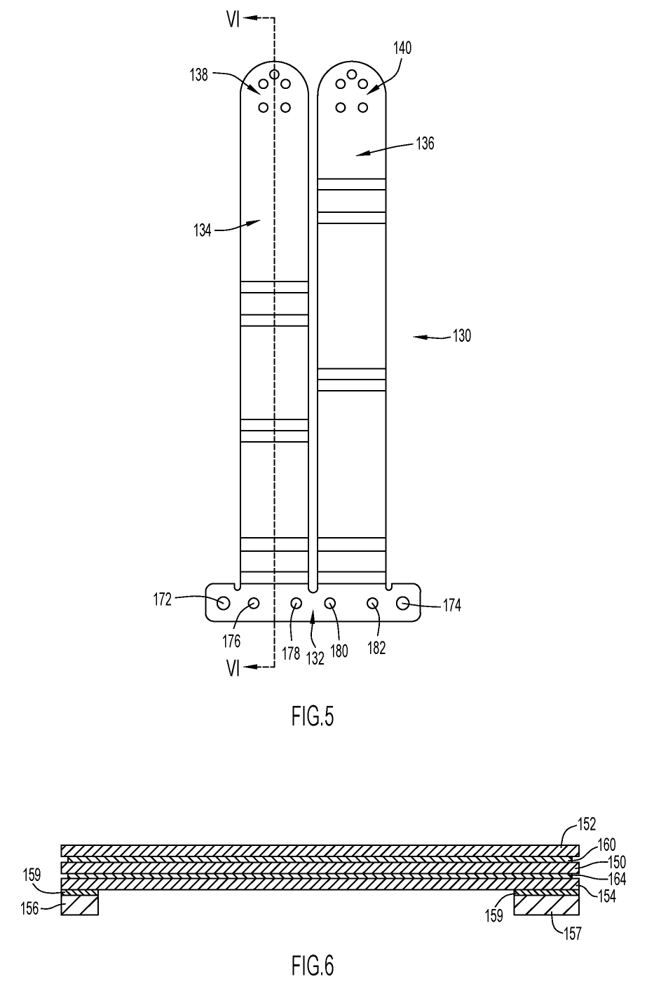

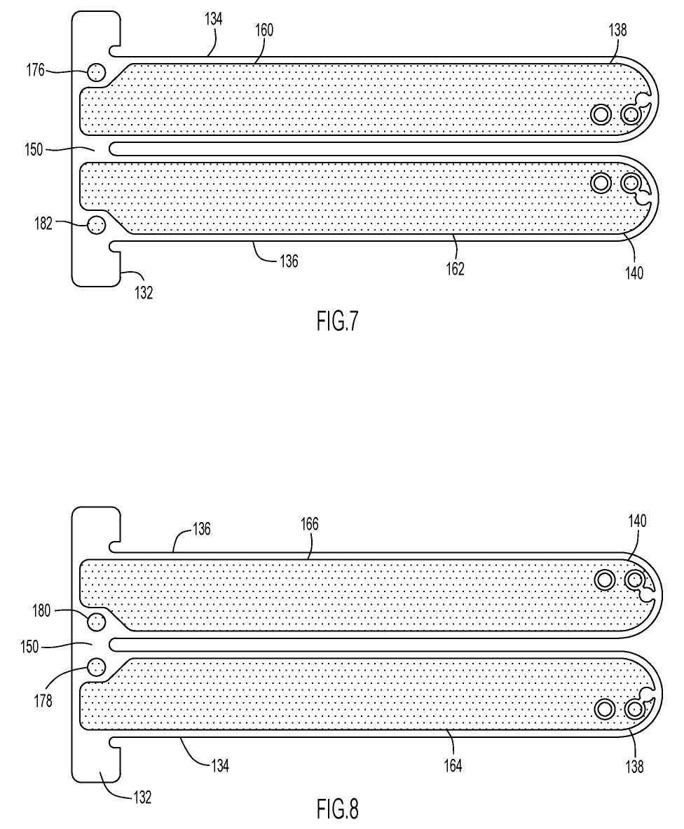

FIG. 6 is a cross-sectional side view of flexible electrical connector 130 taken along line VI-VI in FIG. 5 through first ribbon-shaped branch 134. For ease of visualization, the thicknesses of the layers shown in FIG. 6 are not drawn to scale. Second ribbon-shaped branch 136 has the same cross-sectional profile as first ribbon-shaped branch 134. Flexible electrical connector 130 can be constructed, for example, in accordance with the IPC-2223 Type 2 standard (sectional design standard for flexible/rigid-flexible printed boards). A flexible dielectric layer 150 serves as a center, base layer of connector 130 and can be, for example, an adhesiveless polyimide in accordance with the IPC-4204/11 standard. A plan view of a first, primary side of flexible dielectric layer 150 in a flat, uninstalled configuration is shown in FIG. 7, and a plan view of an opposite, secondary side of flexible dielectric layer 150 is shown in FIG. 8. As shown in FIG. 7, the surface of the primary side of flexible dielectric layer 150 is selectively clad with a metal, such as copper, to provide electrical paths from common end terminal 132 to first and second end terminals 138, 140 of ribbon-shaped branches 134, 136. Specifically, a first outbound metal layer 160 on the primary side of flexible dielectric layer 150 along first ribbon-shaped branch 134 provides an outbound electrical path from common end terminal 132 to first end terminal 138, and a second outbound metal layer 162 on the primary side of flexible dielectric layer 150 along second ribbon-shaped branch 136 provides an outbound electrical path from common end terminal 132 to second end terminal 140.

As shown in FIG. 8, the surface of the secondary side of flexible dielectric layer 150 is also selectively metal-clad to provide return electrical paths from first and second end terminals 138, 140 of ribbon-shaped branches 134, 136 to common end terminal 132. Specifically, a first return metal layer 164 on the secondary side of flexible dielectric layer 150 along first ribbon-shaped branch 134 provides a return electrical path from first end terminal 138 to common end terminal 132, and a second return metal layer 166 on the secondary side of flexible dielectric layer 150 along second ribbon-shaped branch 136 provides a return electrical path from second end terminal 140 to common end terminal 132.

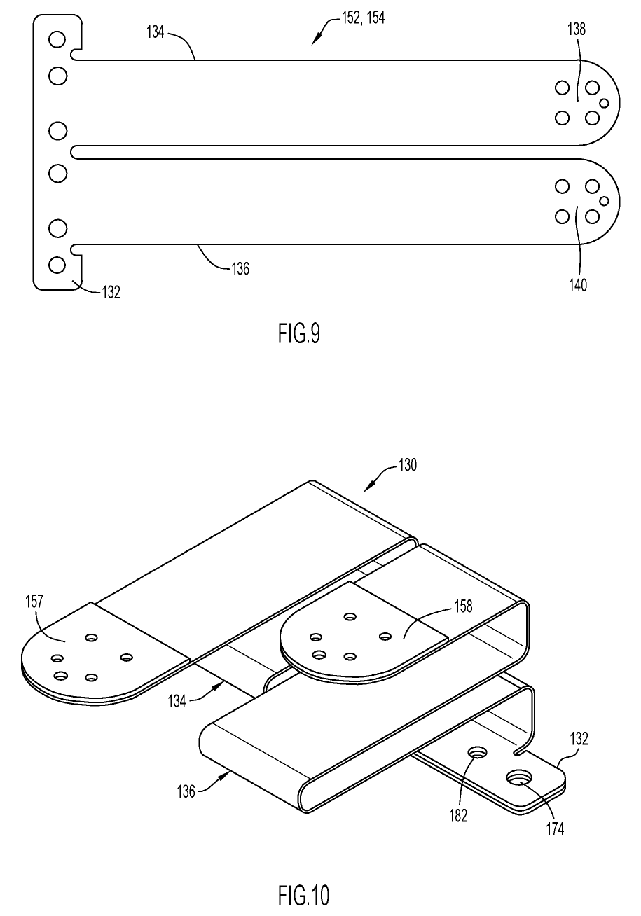

Referring again to FIG. 6, a first flexible cover layer 152 or "coverlay" covers the primary side of metal-clad flexible dielectric layer 150, including outbound metal layers 160, 162. A similar second flexible cover layer 154 covers the secondary side of metal-clad flexible dielectric layer 150, including return metal layers 164, 166. Flexible cover layers 152, 154 can be an acrylic adhesive material, e.g., in accordance with IPC-4203/1 or a polyamide film similar to Kapton tape. A plan view of first flexible cover layer 152 in a flat, uninstalled configuration, which is substantially the same as second flexible cover layer 154, is shown in FIG. 9.

As further shown in FIG. 6, common end terminal 132 is reenforced with a rigid stiffener layer 156, and first end terminal 138 is reenforced with a rigid stiffener layer 157. Similarly, second end terminal 140 is reenforced with a rigid stiffener layer 158 (FIG. 10) that is substantially the same as rigid stiffener layer 157. By way of a non-limiting example, rigid stiffeners 156-158 can be constructed from a woven E-glass and epoxy laminate, e.g., in accordance with IPC-4101/24, /26, or /126. Rigid stiffeners 156-158 can be bonded to the end terminal portions of second flexible cover layer 154 using a flexible adhesive bonding film 159, such as an unsupported acrylic adhesive in accordance with IPC-4203/18, for example. The overall thickness of flexible electrical connector 130 can be approximately 0.015 inches, excluding the end stiffener layers, which can be about 0.06 inches in thickness.

FIG. 10 shows flexible electrical connector 130 in an installed configuration in which branches 134, 136 of flexible electrical connector 130 are bent along parallel axes in a generally folded manner. This installed configuration of flexible electrical connector 130 can also be seen within ESAD 100 in FIGS. 3 and 4, where common end terminal 132 is connected to high-voltage circuit board 120, first ribbon-shaped branch 134 is connected at first end terminal 138 to first initiator device 112, and second ribbon-shaped branch 136 is connected at second end terminal 140 to second initiator device 114. It will be appreciated that the lengths of first and second ribbon-shaped branches 134, 136 are considerably longer than the distance between the connection point on high-voltage circuit board 120 and the initiator devices 112, 114 in the closed lid position of lid 110. This extra length allows first and second ribbon-shaped branches 134, 136 to extend to initiator devices 112, 114 when lid 110 is in the open position to enable attachment of initiator devices 112, 114 during installation/fabrication. However, this extra length requires the ribbon-shaped branches 134, 136 to be bent/folded in the assembled ESAD 100 with lid 110 in the closed position and sealed to the open end of housing 102. As will be described, the orientation of ribbon-shaped branches 134, 136 relative to the hinge axis, as well as the orientation of the attachment of common end terminal 132 to high-voltage circuit board 120, enable the bending of ribbon-shaped branches 134, 136 along axes parallel to the hinge axis with minimal lateral twisting or displacement. The location and orientation of initiator devices 112, 114 also assist in allowing branches 134, 136 to bend in this folded manner.

Each ribbon-shaped branch 134, 136 provides a round-trip circuit connection between its respective initiator device 112, 114 and high-voltage circuit board 120. As shown in FIG. 5, common end terminal 132 includes two outer holes 172, 174 that receive screws to secure flexible electrical connector 130 to high-voltage circuit board 120. Two connection terminals 176, 178 are located on common end terminal 132 adjacent the end of first ribbon-shaped branch 134, which are soldered to high-voltage circuit board 120. One of the connection terminals 178 connects first outbound metal layer 160 in first ribbon-shaped branch 134 to a positive pin or lead on high-voltage circuit board 120, while the other connection terminal 176 connects first return metal layer 164 in first ribbon-shaped branch 134 to a negative pin or lead on high-voltage circuit board 120. The coupling of the first outbound and return metal layers 160, 164 to connection terminals 176, 178 can also be seen in FIGS. 7 and 8. Likewise, two connection terminals 180, 182 are located on common end terminal 132 adjacent the end of second ribbon-shaped branch 136, which are soldered to high-voltage circuit board 120. Connection terminal 180 connects second outbound metal layer 162 in second ribbon-shaped branch 136 to a positive pin or lead on high-voltage circuit board 120, while connection terminal 182 connects second return metal layer 166 in second ribbon-shaped branch 136 to a negative pin or lead on high-voltage circuit board 120. The coupling of the second outbound and return metal layers 162, 166 to connection terminals 180, 182 can also be seen in FIGS. 7 and 8.

As best seen in FIG. 1, each initiator device 112, 114 has five pins, which are respectively coupled to five corresponding terminals on each of first and second end terminals 138, 140. A "dummy" pin of each initiator device 112, 114 engages a center terminal that lies along the longitudinal centerline of the corresponding end terminal 138, 140 and is used to align/orient the electrical pins of each initiator device 112, 114 with the connection terminals of the corresponding end terminal 138, 140. Specifically, as shown in FIGS. 5 and 10, each end terminal 138, 140 has a pair of connection terminals on each side of the longitudinal centerline of ribbon-shaped branch 134, 136. A pair of "positive" pins on each initiator device 112, 114 is soldered to one pair of connection terminals on the corresponding end terminal 138, 140, and a pair of negative pins on each initiator device 112, 114 is soldered to the other pair of connection terminals on the corresponding end terminal 138, 140, in correspondence with the positive/negative connections to high-voltage circuit board 120 at common end terminal 132 in order to make a complete electrical circuit. The use of pairs of pins/connection terminals provides redundancy for reliability. Rigid stiffener layer 156 enhances the mechanical stability of the connection between high-voltage circuit board 120 and common end terminal 132 of flexible electrical connector 130. Similarly, rigid stiffener layers 157, 158 enhance the mechanical stability of the connection between end terminals 138, 140 and initiator devices 112, 114, respectively.

As best seen in FIG. 3, the longitudinal or "length" dimension of common end terminal 132 or "end strip" of flexible electrical connector 130 is connected to high-voltage circuit board 120 along a first direction or axis that is substantially parallel to the hinge axis of lid 110. Consequently, first and second ribbon-shaped branches 134, 136 extend longitudinally from the common end terminal 132 along a second direction substantially perpendicular to the hinge axis. As a result of this perpendicular orientation relative to the hinge axis and to the direction of the common end terminal's connection to high-voltage circuit board 120, when lid 110 is rotated along the hinge axis to its closed position, ribbon-shaped branches 134, 136 tend to bend or fold along axes that are substantially parallel to the hinge axis with minimal lateral twisting or displacement. That is, in the installed position, the longitudinal centerline of first ribbon-shaped branch 134 tends to lie along a first plane perpendicular to the hinge axis and perpendicular to the axis along which common end terminal 132 is connected to high-voltage circuit board 120. Likewise, in the installed position, the longitudinal centerline of second ribbon-shaped branch 136 tends to lie along a second plane parallel to the first plane and perpendicular to the hinge axis and perpendicular to the axis along which common end terminal 132 is connected to high-voltage circuit board 120.

Stated another way, ribbon-shaped branches 134, 136 bend around or "about" a plurality of "axes of bending" that are substantially parallel to each other and to the hinge axis and also to the axis along which common end terminal 132 is connected to high-voltage circuit board 120 such that, in the installed position, over the length of ribbon-shaped branches 134, 136, the direction of the transverse dimension of ribbon-shaped branches 134, 136 (perpendicular to their length) remains substantially parallel to the hinge axis and to the circuit board connection axis over the length of ribbon-shaped branches 134, 136. In effect, all the bends in ribbon-shaped branches 134, 136 are along axes substantially parallel to the single hinge axis such that ribbon-shaped branches 134, 136 fold back and forth without significant lateral twisting or displacement along their length. This arrangement avoids potential damage to flexible electrical connector 130 during installation and closing of ESAD 100, thereby providing a more durable and reliable system.

The position and orientation of initiator devices 112, 114 also contribute to ribbon-shaped branches 134, 136 bending along axes that are parallel to the hinge axis. As shown in FIG. 3, and as also evident from FIGS. 1 and 2, the center points of initiator devices lie along a line or axis that is oriented at an oblique angle relative to the direction of the hinge axis in the installed state (closed lid position). In the example shown in FIG. 3, this orientation causes first initiator device 112 to be positioned such that a shortest line between the center point of first initiator device 112 and common end terminal 132 lies in substantially the same plane (into the page in FIG. 3) as the centerline of first ribbon-shaped branch 134. Likewise, second initiator device 114 is positioned such that a shortest line between the center point of second initiator device 114 and common end terminal 132 lies in substantially the same plane as the centerline of second ribbon-shaped branch 136. The oblique angle of the axis along which initiator devices 112, 114 lie relative to the hinge axis causes the shortest distance between first initiator device 112 and common end terminal 132 to be greater than the shortest distance between second initiator device 114 and common end terminal 132. This angling and offset spacing from the connection point to high-voltage circuit board 120 causes first and second branches 134, 136 to bend at different points along their lengths, as shown in FIG. 10. This arrangement also helps keep the exposed pins of each initiator device at a greater distance from the connector branch of the other initiator device to minimize the risk of entanglement or damage during assembly. Nevertheless, because the two branches are the same length and have substantially the same electrical characteristics, the same amount of energy can be delivered to each of the initiator devices with substantially the same timing despite the different spacing of the initiator devices from the common end terminal.

As shown throughout the figures, e.g., FIGS. 5, 7, and 8, ribbon-shaped branches 134, 136 have substantially the same length, width, thickness, and electrical path length. Ribbon-shaped branches 134, 136 also have substantially the same electrical characteristics, meaning that first ribbon-shaped branch 134 has substantially the same conductive, resistive, inductive, and capacitive characteristics over a range of power levels and temperatures as the second ribbon-shaped branch 136. The two ribbon-shaped branches 134, 136 having substantially the same electrical characteristics enables flexible electrical connector 130 to reliably distribute current supplied by high-power circuit board 120 substantially equally between the two ribbon-shaped branches 134, 136 in parallel to reliably deliver the same amount of energy to the two initiator devices 112, 114. Having the same electrical characteristics in both ribbon-shaped branches 134, 136 ensures that both initiator devices 112, 114 will have the same performance characteristics, thereby reducing development and testing costs for a dual-initiator ESAD design. Having the same performance in the redundant initiator devices is also important for timing reasons.

Using a single flexible electrical connector with two branches, reduces the overall part count of the ESAD relative to a two-connector solution for dual initiator devices, which in turn reduces the circuit board space and improves manufacturability.

Orienting the axis along which initiator devices 112, 114 lie at an oblique angle relative to the longitudinal axis of flexible electrical connector 130 enables placement of initiator devices 112, 114 in a favorable operational location and minimizes the connection footprint on the high-voltage circuit board 120. This orientation also allows ribbon-shaped branches 134, 136 not to overlap the connections to the initiator devices 112, 114, which avoids the potential for the initiator device pins to damage ribbon-shaped branches 134, 136 during vibration and shock events.

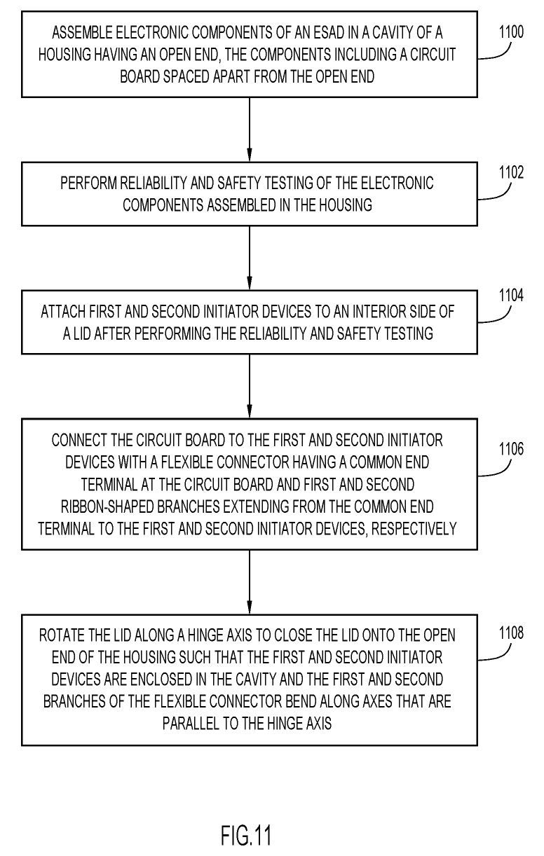

The design of the described ESAD enables safe and efficient assembly and testing. The operations performed in a method of manufacturing an ESAD are summarized in FIG. 11. In operation 1100, electronic components of the ESAD are assembled in the cavity of a housing having an open end. The components include a circuit board spaced apart from the open end, as previously described. Once the electronic components have been assembled, reliability and safety testing of the electronic components is performed in operation 1102. After performing the reliability and safety testing, in operation 1104, first and second initiator devices are attached to a lid of the ESAD.

In operation 1106, the circuit board is connected to the first and second initiator devices, such as LEEFIs, with a flexible electrical connector having a common end terminal at the circuit board and first and second ribbon-shaped branches extending from the common end terminal to the first and second initiator devices, respectively. Finally, in operation 1108, the lid is rotated along a hinge axis to close the lid onto the open end of the housing such that the first and second initiator devices are enclosed in the cavity and the first and second branches of the flexible electrical connector bend along axes that are parallel to the hinge axis. The common end terminal of the flexible electrical connector is connected to the circuit board such that a length dimension of the common end terminal is oriented parallel with the hinge axis, and the first and second branches of the flexible electrical connector extend from the common end terminal perpendicular to the hinge axis. The first and second initiator devices can be attached to the lid along an axis that is oblique to the hinge axis. The lid can be sealed to the housing via laser welding or other welding techniques, for example.

The specific reliability testing to be performed in the manufacturing method is dependent on the design and operational requirements of the ESAD, and the details of such testing are known in the art and beyond the scope of this disclosure. Nevertheless, because the electrical connection provided by the described flexible electrical connector provides the same electrical characteristics for both initiator devices, both initiator devices have the same firing characteristics, which allows a single series of tests, e.g., "Neyer" testing, to be completed to characterize the firing characteristics for both initiator devices.

While the described electronic device is an ESAD having a particular form factor/architecture, it will be appreciated that the concepts described herein apply to other ESAD designs and more generally to other electronic devices with dual or redundant load devices that would benefit from an electrical connector arrangement capable of reliably delivering substantially the same power level or amount of energy to both load devices in parallel from a spaced-apart power source, such as circuit board, connected to the load devices via a connector having dual, parallel electrical circuit paths.

In some aspects, the techniques described herein relate to an electronic device, comprising: a housing enclosing a cavity and having an open end; a lid rotatable along a hinge axis onto the open end of the housing, the lid having an interior side that, in a closed position of the lid, bounds the cavity at the open end of the housing; first and second load devices connected to the lid; a circuit board disposed in the cavity, spaced apart from the open end of the housing; and a flexible electrical connector including: a common end terminal connected to the circuit board, and first and second ribbon-shaped branches extending from the common end terminal to the first and second load devices, respectively, to deliver substantially the same amount of energy from the circuit board to the first and second load devices in response to the common end terminal receiving a voltage signal from the circuit board, wherein the first and second branches of the flexible electrical connector are oriented to bend along axes that are parallel to the hinge axis in the closed position of the lid.

In some aspects, the techniques described herein relate to an electronic device that comprises an electronic safe and arm device, wherein the first and second load devices comprise first and second initiator devices, respectively.

In some aspects, the techniques described herein relate to an electronic device with first and second initiator devices that comprise exploding foil initiators.

In some aspects, the techniques described herein relate to an electronic device, wherein first and second initiator devices each comprise low-energy exploding foil initiators (LEEFIs) and a flexible electrical connector is configured to supply a high-voltage signal to each of the first and second initiator devices.

In some aspects, the techniques described herein relate to an electronic device, wherein a common end terminal of a flexible electrical connector is connected to a circuit board along an axis that is substantially parallel to the hinge axis of the electronic device and first and second branches of the flexible electrical connector extend longitudinally from the common end terminal along a direction substantially perpendicular to the hinge axis.

In some aspects, the techniques described herein relate to an electronic device, wherein first and second load devices are disposed along a first axis that is oblique to the hinge axis of the electronic device, such that the first load device is closer than the second load device to a common end terminal of a flexible electrical connector connecting the load devices to a circuit board.

In some aspects, the techniques described herein relate to an electronic device, wherein first and second branches of a flexible electrical connector have substantially the same electrical characteristics.

In some aspects, the techniques described herein relate to an electronic device, wherein first and second branches of a flexible electrical connector have substantially the same length, width, and thickness.

In some aspects, the techniques described herein relate to an electronic device, wherein the housing of the electronic device has a substantially cylindrical shape.

In some aspects, the techniques described herein relate to an electronic device, wherein: a common end terminal of a flexible electrical connector has a length dimension extending substantially parallel with a hinge axis of the electronic device; first and second ribbon-shaped branches of the flexible electrical connector extend side-by-side from a side of the common end terminal in a direction perpendicular to the hinge axis; and the first and second ribbon-shaped branches each comprise a flexible dielectric layer, a first metal layer on a first side of the flexible dielectric layer to provide an outbound electrical path from the common end terminal, and a second metal layer on a second side of the flexible dielectric layer, opposite the first side, to provide a return electrical path to the common end terminal.

In some aspects, the techniques described herein relate to a flexible electrical connector, comprising an end strip connectable to a circuit board and first and second connector branches extending longitudinally from the end strip to first and second end terminals, respectively. The first connector branch comprises: a first branch of a flexible dielectric layer having a primary side and an opposing secondary side; a first outbound metal layer on the primary side of the first branch of the flexible dielectric layer to provide an outbound electrical path from the end strip to the first end terminal; and a first return metal layer on the secondary side of the first branch of the flexible dielectric layer to provide a return electrical path from the first end terminal to the end strip. The second connector branch comprises: a second branch of the flexible dielectric layer; a second outbound metal layer on the primary side of the second branch of the flexible dielectric layer to provide an outbound electrical path from the end strip to the second end terminal; and a second return metal layer on the secondary side of the second branch of the flexible dielectric layer to provide a return electrical path from the second end terminal to the end strip, wherein the first and second connector branches are ribbon shaped and have substantially the same electrical characteristics to supply substantially the same energy to the first and second end terminals, respectively, in response to receipt of a voltage signal at the end strip.

In some aspects, the techniques described herein relate to a flexible electrical connector, wherein first and second connector branches of the flexible electrical connector have substantially the same length, width, and thickness.

In some aspects, the techniques described herein relate to a flexible electrical connector, wherein first and second end terminals of the flexible electrical connector each include a stiffener layer.

In some aspects, the techniques described herein relate to a flexible electrical connector, wherein an end strip of the flexible electrical connector includes a stiffener layer.

In some aspects, the techniques described herein relate to a flexible electrical connector further comprising: a first cover layer covering first and second outbound metal layers and covering a primary side of a flexible dielectric layer of the flexible electrical connector; and a second cover layer covering first and second return metal layers and covering a secondary side of the flexible dielectric layer of the flexible electrical connector.

In some aspects, the techniques described herein relate to a method of manufacturing an electronic safe and arm device, the method comprising: assembling electronic components of the electronic safe and arm device in a cavity of a housing having an open end, the components including a circuit board spaced apart from the open end; performing reliability and safety testing of the electronic components assembled in the housing; attaching first and second initiator devices to a lid after performing the reliability and safety testing; connecting the circuit board to the first and second initiator devices with a flexible electrical connector having a common end terminal at the circuit board and first and second ribbon-shaped branches extending from the common end terminal to the first and second initiator devices, respectively; and rotating the lid along a hinge axis to close the lid onto the open end of the housing such that the first and second initiator devices are enclosed in the cavity and the first and second branches of the flexible electrical connector bend along axes that are parallel to the hinge axis.

In some aspects, the techniques described herein relate to a method of manufacturing an electronic safe and arm device, wherein connecting the circuit board further comprises: attaching the common end terminal of the flexible electrical connector to the circuit board such that a length dimension of the common end terminal is oriented parallel with the hinge axis, and the first and second branches of the flexible electrical connector extend from the common end terminal perpendicular to the hinge axis.

In some aspects, the techniques described herein relate to a method of manufacturing an electronic safe and arm device, wherein the first and second initiator devices are attached to the lid along an axis that is oblique to the hinge axis.

In some aspects, the techniques described herein relate to a method of manufacturing an electronic safe and arm device, wherein the first and second initiator devices comprise first and second low-energy exploding foil initiator (LEEFI) devices.

In some aspects, the techniques described herein relate to a method of manufacturing an electronic safe and arm device, further comprising sealing the lid to the housing via welding.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. An electronic device, comprising:
a housing enclosing a cavity and having an open end;
a lid rotatable along a hinge axis onto the open end of the housing, the lid having an interior side that, in a closed position of the lid, bounds the cavity at the open end of the housing;
first and second load devices connected to the lid;
a circuit board disposed in the cavity, spaced apart from the open end of the housing; and
a flexible electrical connector including: a common end terminal connected to the circuit board, and first and second ribbon-shaped branches extending from the common end terminal to the first and second load devices, respectively, to deliver substantially the same amount of energy from the circuit board to the first and second load devices in response to the common end terminal receiving a voltage signal from the circuit board, wherein the first and second ribbon-shaped branches of the flexible electrical connector are oriented to bend along axes that are parallel to the hinge axis in the closed position of the lid.

2. The electronic device of claim 1, wherein the electronic device comprises an electronic safe and arm device, and the first and second load devices comprises first and second initiator devices, respectively.

3. The electronic device of claim 1, wherein the first and second load devices comprise exploding foil initiators.

4. The electronic device of claim 3, wherein the first and second load devices comprise low-energy exploding foil initiators (LEEFIs) and the flexible electrical connector is configured to supply a high-voltage signal to each of the LEEFIs.

5. The electronic device of claim 1, wherein the common end terminal is connected to the circuit board along an axis that is substantially parallel to the hinge axis and the first and second ribbon-shaped branches extend longitudinally from the common end terminal along a direction substantially perpendicular to the hinge axis.

6. The electronic device of claim 5, wherein the first and second load devices are disposed along a first axis that is oblique to the hinge axis, such that the first load device is closer to the common end terminal than the second load device.

7. The electronic device of claim 1, wherein the first and second ribbon-shaped branches have substantially the same electrical characteristics.

8. The electronic device of claim 1, wherein the first and second ribbon-shaped branches have substantially the same length, width, and thickness.

9. The electronic device of claim 1, wherein the housing has a substantially cylindrical shape.

10. The electronic device of claim 1, wherein:
the common end terminal of the flexible electrical connector has a length dimension extending substantially parallel with the hinge axis;
the first and second ribbon-shaped branches extend side-by-side from a side of the common end terminal in a direction perpendicular to the hinge axis; and
the first and second ribbon-shaped branches each comprise a flexible dielectric layer, a first metal layer on a first side of the flexible dielectric layer to provide an outbound electrical path from the common end terminal, and a second metal layer on a second side of the flexible dielectric layer, opposite the first side, to provide a return electrical path to the common end terminal.

11. A flexible electrical connector, comprising:
an end strip connectable to a circuit board;
a first connector branch extending longitudinally from the end strip to a first end terminal, the first connector branch comprising:
a first branch of a flexible dielectric layer having a primary side and a secondary side;
a first outbound metal layer on the primary side of the first branch of the flexible dielectric layer to provide an outbound electrical path from the end strip to the first end terminal; and
a first return metal layer on the secondary side of the first branch of the flexible dielectric layer to provide a return electrical path from the first end terminal to the end strip; and
a second connector branch extending longitudinally from the end strip in parallel with the first connector branch, to a second end terminal, the second connector branch comprising:
a second branch of the flexible dielectric layer;
a second outbound metal layer on the primary side of the second branch of the flexible dielectric layer to provide an outbound electrical path from the end strip to the second end terminal; and
a second return metal layer on the secondary side of the second branch of the flexible dielectric layer to provide a return electrical path from the second end terminal to the end strip,
wherein the first and second connector branches are ribbon shaped and have substantially the same electrical characteristics to supply substantially the same energy to the first and second end terminals, respectively, in response to receipt of a voltage signal at the end strip.

12. The flexible electrical connector of claim 11, wherein the first and second connector branches have substantially the same length, width, and thickness.

13. The flexible electrical connector of claim 11, wherein the first and second end terminals each include a stiffener layer.

14. The flexible electrical connector of claim 11, wherein the end strip includes a stiffener layer.

15. The flexible electrical connector of claim 11, further comprising:
a first cover layer covering the first and second outbound metal layers and covering the primary side of the flexible dielectric layer; and
a second cover layer covering the first and second return metal layers and covering the secondary side of the flexible dielectric layer.

16. A method of manufacturing an electronic safe and arm device, the method comprising:
assembling electronic components of the electronic safe and arm device in a cavity of a housing having an open end, the electronic components including a circuit board spaced apart from the open end;
performing reliability and safety testing of the electronic components assembled in the housing;
attaching first and second initiator devices to a lid after performing the reliability and safety testing;
connecting the circuit board to the first and second initiator devices with a flexible electrical connector having a common end terminal at the circuit board and first and second ribbon-shaped branches extending from the common end terminal to the first and second initiator devices, respectively; and
rotating the lid along a hinge axis to close the lid onto the open end of the housing such that the first and second initiator devices are enclosed in the cavity and the first and second ribbon-shaped branches of the flexible electrical connector bend along axes that are parallel to the hinge axis.

17. The method of claim 16, wherein connecting the circuit board further comprises:
attaching the common end terminal of the flexible electrical connector to the circuit board such that a length dimension of the common end terminal is oriented parallel with the hinge axis, and the first and second branches of the flexible electrical connector extend from the common end terminal perpendicular to the hinge axis.

18. The method of claim 16, wherein attaching the first and second initiator devices comprises:
attaching the first and second initiator devices to the lid along an axis that is oblique to the hinge axis.

19. The method of claim 16, wherein attaching the first and second initiator devices comprises attaching first and second low-energy exploding foil initiator (LEEFI) devices.

20. The method of claim 16, further comprising:
sealing the lid to the housing via welding.
